(19) United States
(12) Patent Application Publication
(10) Pub. No.: US 2022/0224191 A1
(43) Pub. Date: Jul. 14, 2022

(54) ELECTRIC MOTOR WITH INJECTION MOULDED STATOR

(71) Applicant: Nidec Corporation, Kyoto (JP)

(72) Inventor: Pascual GUARDIOLA, Ingersheim (DE)

(21) Appl. No.: 17/570,418

(22) Filed: Jan. 7, 2022

(30) Foreign Application Priority Data
Jan. 11, 2021 (DE) 102021100304.0

(51) Int. Cl. H02K 5/22; H02K 15/02; H05K 3/32; H02K 3/28

(52) U.S. Cl. CPC H02K 5/225; H02K 15/02; H02K 2211/03; H02K 3/28; H05K 3/32

(57) ABSTRACT

An electric motor includes a rotor which is mounted rotatably about an axis of rotation and which surrounds a stator on a circumferential side, the stator including stator teeth and coils wound around the stator teeth, the coils being made of a winding wire with winding wire ends, and a printed circuit board. The stator is encapsulated by an injection molding. Receptacles are provided on an upper side of the stator. At least one winding wire end is inserted into the receptacles. An insulation displacement contact is inserted into the receptacles to make electrical contact with the at least one winding wire end. The insulation displacement contact includes a plug-in pin which makes direct electrical contact with the printed circuit board.

### CROSS REFERENCE TO RELATED APPLICATION

The present application claims priority under 35 U.S.C. § 119 to German Application No. 10 2020 100 304.0, filed on Jan. 11, 2021, the entire contents of which are hereby incorporated herein by reference.

### 1. FIELD OF THE INVENTION

The present disclosure relates to an electric motor, and to a method of electrically contacting a stator to a printed circuit board.

### 2. BACKGROUND

Brushless DC motors of the type relevant here are referred to as external rotor motors and have a rotor that is connected to a motor shaft and is rotatably mounted in a housing. The rotor is provided with permanent magnets. Inside the rotor is a stator which carries a number of windings on an iron core. When suitably controlled, the windings generate a magnetic field which drives the rotor to rotate. The windings are usually wound in three phases and are accordingly provided with three electrical connections via which the windings can be connected to a control unit (ECU).

For the purpose of the geometrical description of the electric motor, the axis of rotation of the motor is assumed to be the central axis and the axis of symmetry. The stator is arranged concentrically with the axis of rotation and the rotor. The axis of rotation simultaneously defines an axial direction in which the thickness of the stator pack and the axial length of the motor are specified. Moreover, with respect to the central axis, a radial direction indicates the distance from the central axis, and a circumferential direction is defined tangentially to a certain radius arranged in the radial direction. The connection side of the stator, where the winding wires are connected to the control unit, is described as the top side of the stator.

In such an external rotor motor, the use of conventional busbars is not possible due to the space required.

### SUMMARY

Example embodiments of the present disclosure provide electric motors each having an assembly process which is as automated and inexpensive as possible, in which a contact or a connection between the stator and a printed circuit board is particularly compact and simple.

Accordingly, an electric motor of an example embodiment of the present invention includes a rotor which is mounted rotatably about an axis of rotation and which surrounds a stator on the circumferential side, the stator including stator teeth and coils wound around the stator teeth, and the windings being made from a winding wire with winding wire ends, and with a printed circuit board. The stator is overmolded by injection molding with receptacles being defined on the upper side, at least one winding wire end is inserted into each of the receptacles, and each of the receptacles includes an inserted insulation displacement contact which electrically contacts the at least one winding wire end and which includes a plug-in pin which directly electrically contacts the circuit board. By providing the receptacles with the injection molding, efficiency is increased because higher thermal conductivity is present.

The stator is preferably completely overmolded on an upper side and a lower side, and at least partially overmolded in the region of the circumferential surface.

Since the insulation displacement contact is already attached to the stator during assembly and includes a plug-in pin, the stator can be contacted electrically easily and without taking up much space on the PCB. In addition, the manufacturing costs are low, as no additional components are required.

It is preferably provided that in the region of the magnets, the stator is not overmolded and includes recesses to increase the power transmission of the electric motor.

Preferably, the printed circuit board includes through-penetrating recesses, in each of which a plug-in pin engages. This makes contacting particularly easy.

The winding wire ends are preferably bent outwards in the radial direction and inserted into the corresponding receptacle. The receptacles are thus located on the outside of the stator surface in the radial direction, making them easily accessible.

In an advantageous example embodiment of the present disclosure, the receptacles extend with their longitudinal axes parallel or substantially parallel to the longitudinal axis of the stator, are pocket-shaped and rectangular or substantially rectangular in cross-section with two longitudinal sides and two transverse sides, each pocket including an opening which is located on the side remote from the stator. The longitudinal sides extend tangentially, in the circumferential direction of the longitudinal axis. On an end surface remote from the stator, the receptacles each include, on an inner longitudinal side, an incision which extends parallel or substantially parallel to the longitudinal axis and into which the at least one winding wire end is inserted. The receptacles are particularly easy to form by injection molding. In addition, they can accommodate the insulation displacement contacts in a secure and defined manner.

The receptacles are preferably evenly spaced from one another in a circumferential direction, with a total of three being provided, all of which extend over an angular range of less than about 120°. Due to the spacing, it is possible to separately guide the wires of the individual phases. However, since the spacing is small, pressing in into the printed circuit board is simplified.

The electric motor preferably includes three phase groups, each phase group having two winding wire ends which are inserted into a common one of a total of three receptacles and which are electrically contacted by a common insulation displacement contact.

It is advantageous if the electric motor includes 10 poles and 12 stator teeth.

It is preferable that the winding wire ends are held on the upper surface of the stator by a wire holder made by injection molding, so that the position of the wire holder is secured.

The injection molding process is preferably carried out with plastic or resin.

Furthermore, an electric pump with a previously described electric motor is provided.

Also provided is a method of electrically contacting a stator of an electric motor including a printed circuit board. The stator includes stator teeth and coils wound on the stator teeth, and the windings are made from a winding wire having winding wire ends and the winding wire ends extend parallel or substantially parallel to the longitudinal axis of the stator. The method includes overmolding of the stator by injection molding and formation of receptacles on the upper side of the stator, bending of the winding wire ends in radial direction to the longitudinal axis to the outside and insertion into the receptacles, inserting one insulation displacement contact at a time into a receptacle, whereby the winding wire ends are electrically contacted with the insulation displacement contacts, each insulation displacement contact including a plug-in pin, placing the stator with respect to the printed circuit board, the printed circuit board and the stator being aligned with their upper and lower sides parallel or substantially parallel to one another and, preferably, the longitudinal axes being congruent or substantially congruent, and simultaneous insertion, in particular pressing, of the plug-in pins of the insulation displacement contacts into recesses of the printed circuit board in the longitudinal direction to electrically contact the printed circuit board with the winding wires.

The process is particularly simple and space-saving and therefore also cost-effective.

Preferably, an electric motor according to an example embodiment of the present disclosure may have any of the above features.

The above and other elements, features, steps, characteristics and advantages of the present disclosure will become more apparent from the following detailed description of the example embodiments with reference to the attached drawings.

### BRIEF DESCRIPTION OF THE DRAWINGS

Example embodiments of the present disclosure are explained in more detail below with reference to the drawings. Similar or similarly acting components are designated in the figures with the same reference signs.

FIG. 1 is a spatial view of a stator with insulation displacement contacts according to an example embodiment of the present invention.

FIG. 2 is a schematic diagram of the winding scheme of the stator of FIG. 1.

FIG. 3 is a sectional view of the stator of FIG. 1.

FIG. 4 is an illustration of the mounting of the stator on the printed circuit board.

### DETAILED DESCRIPTION

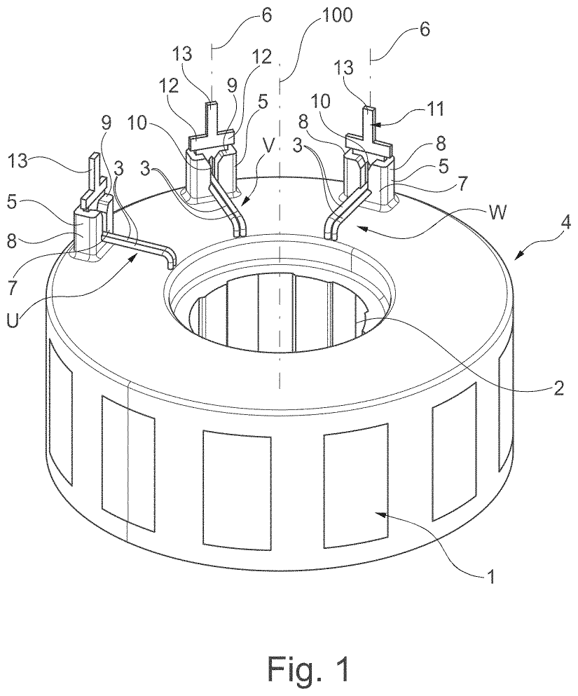

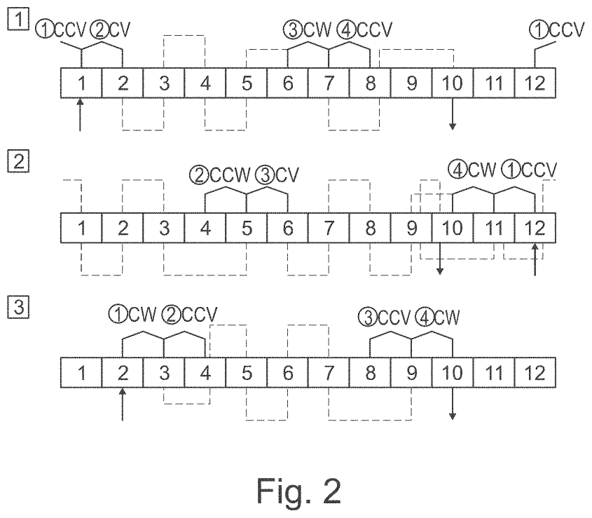

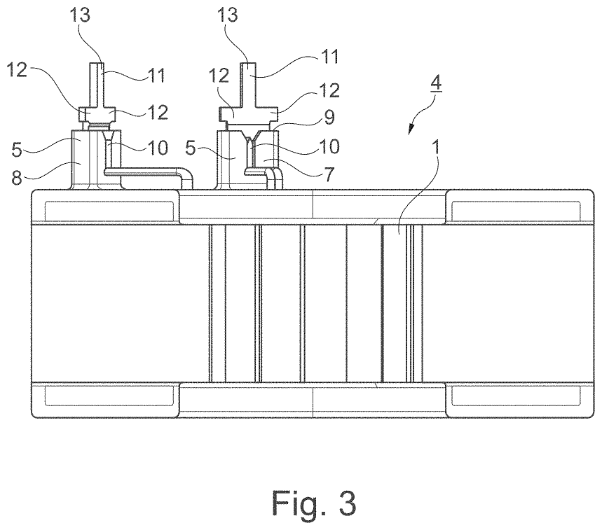

FIGS. 1 and 3 show a stator 1 extending coaxially with a longitudinal axis 100 and having a plurality of stator teeth, shown only schematically, around which respective coils, not shown, are wound. The stator teeth are arranged sequentially in the circumferential direction of the stator 1. The stator teeth are formed of laminations. The stator 1 is fixedly mounted within a housing of an electric motor, and is adapted to generate a time-varying magnetic field by the coils. A magnetized outer rotor, not shown, is thereby mounted within a central opening 2 of the stator 1. It is arranged to be rotated by an interaction with the time-varying magnetic field generated by the coils. A wire holder, not shown, is adapted to position the winding wire end portions of the wound coils of the stator 1. The wire holder is arranged on the upper side of the stator 1. In this regard, the coils are grouped into three phase groups U, V, W. For each phase group, two winding wire ends 3 are seen on the upper side of the stator 1. The exemplary electric motor has 10 poles and 12 stator teeth. The winding diagram is shown in FIG. 2.

The stator 1 with the wire holder is overmolded with plastic or resin in an injection molding process. The resulting stator unit 4 is shown in FIGS. 1 and 3. In the injection molding process, three receptacles 5 are also formed on the upper surface of the stator unit 4 with their longitudinal axes 6 extending parallel to the longitudinal axis 100. The receptacles 5 are pocket-shaped and substantially rectangular in cross-section, with two longitudinal sides 7 and two transverse sides 8. The openings of the pockets 9 are located on the side remote from the stator, at the top. The longitudinal sides 7 extend tangentially, in the circumferential direction of the longitudinal axis 100. On the end side remote from the stator, the receptacles 5 each have an incision 10 in the form of a slot on the inner longitudinal side 7. The slot 10 extends parallel to the longitudinal axis 100 and is provided for receiving the winding wire ends 3. The receptacles are evenly spaced from one another in the circumferential direction. All three together extend in total over an angular range of less than 120°. After the stator 1 has been overmolded by injection molding and the receptacles 5 have been formed, the winding wire ends 3 projecting from the end surface of the stator unit are bent outward in the radial direction and inserted into the respective slot 10 of the receptacle 5. Then, an insulation displacement contact (IDC) 11 is inserted into each receptacle 5 from above into the opening 9. The insulation displacement contact 11 has a clamping slot, not shown, into which one or more winding wire ends 3 can be received as required. When the insulation displacement contacts 11 are inserted into the pockets of the receptacles 5, the clamping slots are pushed onto the winding wire ends 3 lying in the receptacles and connected to the receptacles. By a sharp contact in the clamping slots, the insulation of the winding wire ends 3 is cut and an electrical contacting of the wire core of the winding wire is achieved. Adjacent to the clamping slot area, the insulation displacement contacts 11 have two projections 12 which limit the insertion path and which, in the inserted state, each lie in contact with the end surface of the receptacle 5. Only the clamping slot area lies in the pocket of the receptacle 5 in the assembled state. A plug-in pin 13 is connected to each of the projections 12 on the side remote from the clamping slot. The plug-in pin 13 is provided for making electrical contact between the insulation displacement contact 11 and a printed circuit board.

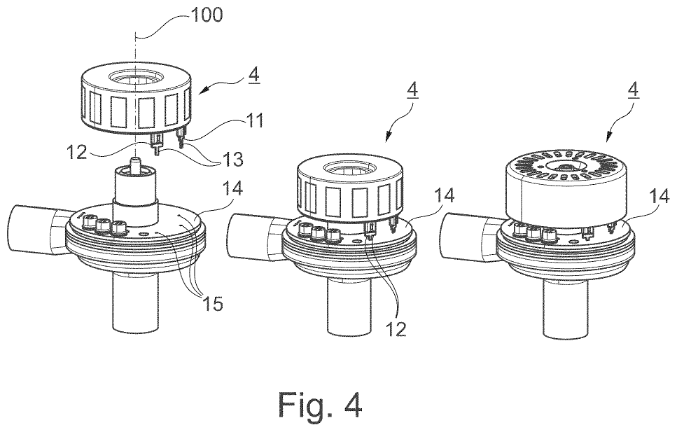

FIG. 4 schematically shows the mounting of the stator unit 4 on the printed circuit board 14. The printed circuit board has interspersed recesses 15 at corresponding points for receiving the plug-in pins 13. The stator unit is placed centrally above the printed circuit board 14, so that the longitudinal axis of the stator unit 100 and the axis of symmetry of the printed circuit board are congruent. The stator unit 4 is fed longitudinally onto the printed circuit board 14 until the plug pins 13 are placed directly above the recesses 15. The plug pins 13 are then pressed into the recesses 15. The projections 12 of the insulation displacement contacts 11 also limit the press-fit operation in this direction. The electrical connection of the printed circuit board 14 to the phase windings is particularly simple due to the insulation displacement contacts inserted in the stator unit, and requires a minimum of installation space.

The described stator unit 4 is preferably part of a brushless DC motor which in turn is preferably part of a pump.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electric motor, comprising:
a printed circuit board;
a rotor which is mounted rotatably about an axis of rotation; and
a stator which is surrounded by the rotor; wherein
the stator includes stator teeth and coils wound around the stator teeth, the coils being made from a winding wire with winding wire ends;
the stator is overmolded by an injection molding which defines receptacles on an upper side of the stator;
at least one of the winding wire ends is inserted into each of the receptacles to contact an insulation displacement contact; and
the insulation displacement contact makes electrical contact with the at least one winding wire end and includes a plug-in pin which makes direct electrical contact with the printed circuit board.

2. The electric motor according to claim 1, wherein the printed circuit board includes recesses in which each of the plug-in pins are engaged.

3. The electric motor according to claim 1, wherein the winding wire ends are bent outwards in a radial direction and inserted into corresponding ones of the receptacles.

4. The electric motor according to claim 1, wherein
the receptacles extend with longitudinal axes thereof parallel or substantially parallel to a longitudinal axis of the stator, and are pocket-shaped and rectangular or substantially rectangular in cross-section with two longitudinal sides and two transverse sides;
each of the pocket-shaped receptacles includes an opening which is located on an upper surface remote from the stator, and the two longitudinal sides extend tangentially from a circumferential direction of the longitudinal axis;
on the upper surface remote from the stator, the receptacles each include, on one of the two longitudinal side on the inside in a radial direction, an incision which extends parallel or substantially parallel to the longitudinal axis of the stator and into which the at least one winding wire end is inserted.

5. The electric motor according to claim 1, wherein the receptacles are evenly spaced from each other in a circumferential direction and extend collectively over an angular range of less than about 120°.

6. The electric motor according to claim 1, wherein the electric motor includes three phase groups, each of which including two winding wire ends which are inserted into a common one of a total of three of the receptacles and which are electrically contacted by a common one of the insulation displacement contacts.

7. The electric motor according to claim 1, wherein the electric motor includes 10 poles and 12 stator teeth.

8. The electric motor according to claim 1, wherein the winding wire ends are held on the upper side of the stator by a wire holder which is overmolded by the injection molding.

9. The electric motor according to claim 1, wherein the injection molding is made of plastic or resin.

10. An electric pump comprising the electric motor according to claim 1.

11. A method of electrically contacting a stator of an electric motor with a printed circuit board, the stator includes stator teeth and coils wound on the stator teeth, and the coils are made from a winding wire including winding wire ends which extend parallel or substantially parallel to a longitudinal axis of the stator, the method comprises:
a) overmolding of the stator by injection molding, to form receptacles on an upper side of the stator;
b) bending the winding wire ends outwards in a radial direction to the longitudinal axis and inserting the winding wire ends into the receptacles;
c) inserting insulation displacement contacts into a receptacle to provide electrical contacting of the winding wire ends with the insulation displacement contacts, each of the insulation displacement contacts including a plug-in pin;
d) positioning the stator with respect to the printed circuit board, the printed circuit board and the stator such that upper and lower surfaces thereof are aligned parallel or substantially parallel to each other;
e) simultaneously pressing the plug-in pins of the insulation displacement contacts into the recesses of the printed circuit board in the longitudinal direction to make electrical contact between the printed circuit board and the winding wires.

12. The method according to claim 11, wherein
the receptacles extend with longitudinal axes thereof being parallel or substantially parallel to the longitudinal axis of the stator, are pocket-shaped and rectangular or substantially rectangular in cross-section with two longitudinal sides and two transverse sides, openings of the receptacles are located on an upper surface remote from the stator, and the two longitudinal sides extend tangentially from a circumferential direction of the longitudinal axis;
on the upper surface remote from the stator, the receptacles each include, on one of the two longitudinal side on the inside in a radial direction, an incision defined by a slot which extends parallel or substantially parallel to the longitudinal axis of the stator; and
at least one winding wire end is inserted into the slot.

13. The method according to claim 11, wherein the receptacles are evenly spaced from each other in a circumferential direction and extend together over an angular range of less than about 120°.

14. The method according to claim 11, wherein the electric motor includes three phase groups, each of the phase groups including two of the winding wire ends which are inserted into a common one of the receptacles and which are electrically contacted by a common one of the insulation displacement contacts.

15. The method according to claim 11, wherein the electric motor includes 10 poles and 12 stator teeth.

16. The method according to claim 11, wherein the winding wire ends are held on the upper side of the stator by a wire holder which is overmolded in the injection molding process of step a).

17. The method according to claim 11, wherein the injection molding process in step a) is carried out with plastic or resin.

18. The method according to claim 11, wherein the electric motor is a portion of an electric pump and the electric motor includes an external rotor.
